(19) United States
(12) Patent Application Publication
(10) Pub. No.: US 2024/0027506 A1
(43) Pub. Date: Jan. 25, 2024

(54) SMART 3D ENERGY PROBES FOR STOCHASTIC FIELDS

(71) Applicant: EV-TECHNOLOGIES, COLOMBELLES (FR)

(72) Inventor: Sidina WANE, COLOMBELLES (FR)

(21) Appl. No.: 18/245,803

(22) PCT Filed: Sep. 20, 2021
(86) PCT No.: PCT/EP2021/075815

§ 371 Date: Mar. 17, 2023

(30) Foreign Application Priority Data
Sep. 18, 2020 (EP) 20306051.2
Oct. 2, 2020 (EP) 20306144.5

(51) Int. Cl. G01R 29/08; G01R 33/00

(52) U.S. Cl. CPC G01R 29/0878; G01R 29/0871; G01R 33/0029; G01R 33/0094; G01R 33/0005

(57) ABSTRACT

The present disclosure relates to a probe for sensing magnetic and electric fields comprising: first and second sensing elements (102, 104), each comprising first and second terminals (106, 108), the sensing elements being orientated in opposite directions from each other (x+, x−); and a measurement circuit configured to either: measure voltage and current across the first and second terminals (106, 108) of each of the sensing elements (102, 104) to detect electric and magnetic fields; or to couple the first terminals (106) of each of the sensing elements (102, 104) to a reference voltage (GND) and to measure a voltage present at the second terminal (108) to detect an electric field, and to couple the first terminal (108) of each of the sensing elements (102, 104) to an open circuit impedance (Zo) and to measure a current present at the second terminal (108) to detect a magnetic field.

The present patent application claims priority from the European patent application no. EP20306051 filed on 18 Sep. 2020, and from the European patent application no. EP20306144 filed on 2 Oct. 2020, the contents of these applications being hereby incorporated by reference.

### TECHNICAL FIELD

The present disclosure relates generally to the electric and magnetic field probes, and in particular to probes capable of sensing both electric and magnetic fields.

### BACKGROUND ART

The near-field detection of electric fields and of magnetic fields each has its uses for certain applications, but has its limits. A measurement of the power or energy density provides a more universal measurement index. Based on Maxwell's equations, it is possible to determine the power or energy density based on simultaneous measurements of the electric and magnetic field.

However, there is a need for a technical solution for simultaneously measuring electric and magnetic fields in one or more directions.

### SUMMARY OF INVENTION

It is an aim of embodiments of the present disclosure to at least partially address one or more needs in the prior art.

According to one aspect, there is provided a probe for sensing magnetic and electric fields comprising: first and second sensing elements, each sensing element comprising first and second terminals, the sensing elements being orientated in opposite directions from each other; and
a measurement circuit configured to either:
a) measure voltage and current across the first and second terminals of each of the sensing elements in order to detect electric and magnetic fields; or
b) to couple the first terminal of each of the sensing elements to a reference voltage and to measure a voltage present at the second terminal of each of the sensing elements in order to detect an electric field, and to couple the first terminal of each of the sensing elements to an open circuit impedance and to measure a current present at the second terminal of each of the sensing elements in order to detect a magnetic field.

According to one embodiment, the measurement circuit is configured to perform b), the measurement circuit comprising:
at least one first switch capable of connecting the first terminal of the first sensing element:
   to the open-circuit impedance such that the first sensing element forms one branch of a dipole antenna for measuring the electric field, the second terminal of the first sensing element forming a signal port; or
   to the reference voltage rail via an impedance such that the first sensing element is capable of forming a magnetic field sensor, the second terminal of the first sensing element forming a signal port; and
at least one second switch configured to connect the first terminal of the second sensing element either:
   to an open-circuit impedance such that the second sensing element forms the other branch of the dipole antenna for measuring the electric field, the second terminal of the second sensing element forming a signal port; or
   to a reference voltage rail via an impedance such that the second sensing element is capable of forming a magnetic field sensor, the second terminal of the second sensing element forming a signal port.

According to one embodiment, the probe further comprises at least one spin-wave sensor, wherein the spin-wave sensor is for example biased by a biasing voltage, the biasing voltage for example being a DC biasing voltage.

According to one embodiment, the first and second sensing elements are dimensioned to receive frequencies of at least 1 GHz, and for example of at least 30 GHz.

According to one embodiment, the first and second sensing elements are formed in WLCSP (wafer-level-chip-scale-packaging) technology.

According to one embodiment, each of the first and second sensing elements is implemented by a coil.

According to a further aspect, there is provided a 3D energy probe comprising:
a first probe as above having first and second sensing elements oriented to sense fields in an x direction;
a second probe as above having first and second sensing elements oriented to sense fields in a y direction substantially perpendicular to the x direction; and
a third probe as above having at least a first sensing element oriented to sense fields in a z direction substantially perpendicular to the x or y directions.

According to a further aspect, there is provided a probe array having a plurality of probing elements arranged in at least two columns and at least two rows, each probing element comprising the above probe or the 3D energy probe.

According to one embodiment, the first and second terminals of each sensing element are coupled to the measuring circuit, or to a signal processing circuit, via a connector, the connector comprising:
a male portion comprising at least two pins, surrounded by a metallic shielding tube; and/or
a female portion comprising at least two sockets, surrounded by a metallic shielding tube.

According to one embodiment, each socket comprises a metal tube configured to receive, and make electrical contact with, a corresponding one of the at least two pins.

According to one embodiment, the metallic shielding tube is fixed to a body of the male portion of the connector, the body having, for each pin, a through-hole in which the pin is centrally positioned.

According to one embodiment, each pin is separated from the inside surface of its through-hole by a separation of at least 0.1 mm.

According to one embodiment, each pin is separated from each other pin by a spacing of at least 0.5 mm, and/or the centers of the pins are separated by a distance of at least 0.5 mm.

According to one embodiment, the metallic shielding tube is cylindrical, with an inner diameter 10 mm or less.

According to one embodiment, the at least two pins and/or the metallic shielding tube is formed of copper, aluminum, or gold.

According to one embodiment, the connector comprising the male portion and the female portion, wherein, when engaged with each other, the metallic shielding tube of the male portion aligns with and electrically contacts the metallic shielding tube of the female portion.

According to a further aspect, there is provided a cable having at one of its extremities the male portion of the connector of the above probe, or 3D energy probe, the cable comprising a first wire coupled to a first of the pins and a second wire coupled to a second of the pins, each wire being shielded by a corresponding metallic sleeve.

According to a further aspect, there is provided a cable having at one of its extremities the female portion of the connector of the above probe, or 3D energy probe, the cable comprising a first wire coupled to a first of the sockets and a second wire coupled to a second of the sockets, each wire being shielded by a corresponding metallic sleeve.

According to one embodiment, the first and second terminals of each sensing element are coupled to the measuring circuit, or to a signal processing circuit, further via one or more polymer-based waveguiding structures, wherein each polymer-based waveguide structure comprises a plurality of waveguides, each waveguide being coupled to corresponding pin of the connector.

According to a further aspect, there is provided a modular MIMI (multiple-inputs, multiple outputs) circuit comprising a plurality of correlators configured to couple a plurality of the above probes, or 3D energy probes, to a signal processor.

According to one aspect, there is provided an instrument interface device providing a wireless interface between a signal analysis instrument and a DUT (device under test), the instrument interface device comprising a connector for connecting to a port of the signal analysis instrument, and a receiver for wirelessly receiving one or more input signals representing one or more DUT signals present at the DUT. The receiver for example comprises a down converter for demodulating the one or more input signals, and a digital to analog converter for converting the one or more demodulated signals into one or more analog signals to be provided to the port via the connector. The receiver is for example configured for receiving the input signal having a frequency of between 50 and 120 GHz. The instrument interface device for example further comprises a mosaic correlator for converting M input signals received by the receiver into N input signals to be provided to the signal analysis equipment, wherein M is greater than N, the mosaic correlator corresponding for example to an ASIC correlator as described in the publication entitled “Cognitive Beamformer Chips with Smart-Antennas for 5G and Beyond: Holistic RFSOI Technology Solutions including ASIC Correlators”, S. Wane et al., provided in attachment.

According to a further aspect, there is provided a DUT interface device providing a wireless interface between a DUT (device under test) and a signal analysis instrument, the DUT interface device comprising a connector for connecting to a port of the DUT, and a transmitter for wirelessly transmitting an input signal to the signal analysis instrument, the input signal representing one or more DUT signals present at the DUT. The transmitter for example comprises an analog to digital converter for converting one or more DUT signals into a digital signal, and a modulator for modulating the digital signal to generate the input signal. The transmitter is for example configured for transmitting a signal of between 50 and 120 GHz.

According to yet a further aspect, there is provided a test system for testing a DUT (device under test) comprising: the above instrument interface device; and the above DUT interface device. The test system for example further comprises the signal analysis instrument, which is for example: a VNA (vector network analyzer), such as a contactless VNA; and/or an oscilloscope; and/or a spectrum-analyzer.

According to a further aspect, there is provided a method of determining calibration parameters of the instrument interface device of the above test system, comprising providing two of the instrument interface devices arranged back-to-back, and coupling the connector of each instrument interface device to co-array signal-processing and synchronization equipment.

According to yet a further aspect, there is provided a calibration device for calibrating the above test system, comprising a communications interface for communicating with the instrument interface device, and a communications interface for communicating with the DUT interface device, and a calibration circuit configured to determine at least a voltage offset and/or a phase offset introduced by the instrument interface device and/or by the DUT interface device.

According to yet a further aspect, there is provided a communications cable comprising: a first connector at a first end of the cable; a second connector at the second end of the cable, the first and second connectors each comprising at least a first contact, the first contacts of the first and second connectors being coupled together via a wire; and a monitoring circuit for monitoring, for example by proximity coupling, one or more signals propagated over the wire. The communications cable for example further comprising a wireless communications circuit for wirelessly communicating with one or more remote devices. The wireless communications circuit is for example configured to transmit to the one or more remote devices a signal representative of one or more signals propagated over the wire.

According to a further aspect, there is provided a calibration system for determining electrical characteristics of the above cable, comprising a calibration device configured to communicate with the above wireless communications circuit.

According to a further aspect, there is provided connector for propagating one or more signals, such as RF signals, the connector comprising: a male portion comprising at least two pins, for example surrounded by a metallic shielding tube; and/or a female portion comprising at least two sockets, for example surrounded by a metallic shielding tube. Each socket for example comprises a metal tube configured to receive, and make electrical contact with, a corresponding one of the at least two pins. The metallic shielding tube is for example fixed to a base portion of the male portion of the connector, the base portion having, for each pin, a through-hole in which the pin is centrally positioned. Each pin is for example separated from the inside surface of its through-hole by a separation of at least 0.1 mm. In some embodiments, each pin is separated from each other pin by a spacing of at least 0.5 mm, and/or the centers of the pins are separated by a distance (δ) of at least 0.5 mm. The metallic shielding tube is for example cylindrical, with an inner diameter 10 mm or less. The at least two pins and/or the metallic shielding tube is for example formed of copper, aluminum, or gold. According to one embodiment the connector comprises both the male portion and the female portion, wherein, when engaged with each other, the metallic shielding tube of the male portion aligns with and electrically contacts the metallic shielding tube of the female portion. According to another embodiment, the connector comprises the male portion and the female portion, wherein female portion has no metallic shielding tube surrounding the at least two sockets, and comprises a first metallic shielding tube surrounding a first of the sockets, and a second metallic shielding tube surrounding a second of the sockets, the first and second metallic shielding tubes for example being electrically connected together. The connector is for example configured to make: at least two module to module connections; at least two module to cable connections; or a connection from a module or cable to each terminal of a dipole antenna.

According to a further aspect, there is provided a cable having at one of its extremities the male portion of the above connector, the cable comprising a first wire coupled to a first of the pins and a second wire coupled to a second of the pins, each wire being shielded by a corresponding metallic sleeve.

According to yet a further aspect, there is provided a cable having at one of its extremities the female portion of the above connector, the cable comprising a first wire coupled to a first of the sockets and a second wire coupled to a second of the sockets, each wire being shielded by a corresponding metallic sleeve.

According to a further aspect, there is provided an instrument interface device providing a wireless interface between a signal analysis instrument and a DUT (device under test), the instrument interface device comprising the above connector for connecting to a port of the signal analysis instrument, and a receiver for wirelessly receiving one or more input signals representing one or more DUT signals present at the DUT. The receiver for example comprises a down converter for demodulating the one or more input signals, and a digital to analog converter for converting the one or more demodulated signals into one or more analog signals to be provided to the port via the connector. The receiver is for example configured for receiving the input signal having a frequency of between 50 and 120 GHz. The instrument interface device for example further comprises a mosaic correlator for converting M input signals received by the receiver into N input signals to be provided to the signal analysis equipment, wherein M is greater than N, the mosaic correlator corresponding for example to an ASIC correlator as described in the publication entitled “Cognitive Beamformer Chips with Smart-Antennas for 5G and Beyond: Holistic RFSOI Technology Solutions including ASIC Correlators”, S. Wane et al.

According to a further aspect, there is provided a DUT interface device providing a wireless interface between a DUT (device under test) and a signal analysis instrument, the DUT interface device comprising the above connector for connecting to a port of the DUT, and a transmitter for wirelessly transmitting an input signal to the signal analysis instrument, the input signal representing one or more DUT signals present at the DUT. The transmitter for example comprises an analog to digital converter for converting one or more DUT signals into a digital signal, and a modulator for modulating the digital signal to generate the input signal. The transmitter is for example configured for transmitting a signal of between 50 and 120 GHz.

According to a further aspect, there is provided a test system for testing a DUT (device under test) comprising: the above instrument interface device; and the above DUT interface device. The test system for example further comprising the signal analysis instrument, which is for example: a VNA (vector network analyzer), such as a contactless VNA; and/or an oscilloscope; and/or a spectrum-analyzer.

According to a further aspect, there is provided a method of determining calibration parameters of the instrument interface device of the above test system, comprising providing two of the instrument interface devices arranged back-to-back, and coupling the connector of each instrument interface device to co-array signal-processing and synchronization equipment.

According to yet a further aspect, there is provided a calibration device for calibrating the above test system, comprising a communications interface for communicating with the instrument interface device, and a communications interface for communicating with the DUT interface device, and a calibration circuit configured to determine at least a voltage offset and/or a phase offset introduced by the instrument interface device and/or by the DUT interface device.

According to a further aspect, there is provided a communications cable comprising: a first connector as above at a first end of the cable; a second connector at the second end of the cable, the first and second connectors each comprising at least a first contact, the first contacts of the first and second connectors being coupled together via a wire; and a monitoring circuit for monitoring, for example by proximity coupling, one or more signals propagated over the wire. The communications cable for example further comprises a wireless communications circuit for wirelessly communicating with one or more remote devices. The wireless communications circuit is for example configured to transmit to the one or more remote devices a signal representative of one or more signals propagated over the wire.

According to a further aspect, there is provided a calibration system for determining electrical characteristics of the above cable, comprising a calibration device configured to communicate with the above wireless communications circuit.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 schematically illustrates an electric/magnetic field probe according to an embodiment of the present disclosure;

FIG. 2 is a plan view of a coil module of an X and Y electric/magnetic field probe according to an embodiment of the present disclosure;

FIG. 3 schematically represents an X and Y electric/magnetic field probe comprising the coil module of FIG. 2;

FIG. 4 schematically represents an X and Y electric/magnetic field probe comprising the coil module of FIG. 2 according to an alternative embodiment to that of FIG. 3;

FIG. 5 schematically represents an X and Y electric/magnetic field probe comprising the coil module of FIG. 2 according to an alternative embodiment to those of FIGS. 3 and 4;

FIG. 6 is a perspective view of a coil of the electric/magnetic field probe of FIG. 1 according to an example embodiment;

FIG. 7 is a perspective view of a coil of the electric/magnetic field probe of FIG. 1 according to another example embodiment;

FIG. 8 schematically illustrates a sensing device according to an example embodiment of the present disclosure;

FIG. 9 schematically illustrates an electric/magnetic field sensing probe capable of sensing electric and magnetic fields in X, Y and Z directions according to an example embodiment of the present disclosure;

FIG. 10 is a plan view of a coil module of an X, Y and Z electric/magnetic field probe according to an embodiment of the present disclosure;

FIG. 11 schematically illustrates a sensing device for electric/magnetic field sensing in X, Y and Z, according to an example embodiment;

FIG. 12 schematically illustrates an electric/magnetic field sensing probe capable of sensing electric and magnetic fields in X, Y and Z directions and further comprising spin-wave detectors according to an example embodiment of the present disclosure;

FIG. 13 is a top view of one of the spin-wave sensors of FIG. 12 according to an example embodiment of the present disclosure;

FIG. 14 schematically illustrates a spin-wave sensor according to an example in which it is referenced to ground;

FIG. 15 schematically illustrates a spin-wave sensor according to an example in which it is biased by a DC voltage;

FIG. 16 schematically illustrates a front-end module of FIG. 11 in more detail in the case that it is a dual pin-based six port switched front end module;

FIG. 17 schematically illustrates a front-end module of FIG. 11 in more detail in the case that it is a two-pin-based twelve-port non-switched front-end module;

FIG. 18 illustrates a two-pin connector with two-socket plug according to an example embodiment of the present disclosure;

FIG. 19 schematically illustrates a front-end module of FIG. 11 in more detail in the case that it is a three pin-based six-port switched front end module;

FIG. 20 schematically illustrates a simultaneous 3D electric and magnetic field sensing mode of a pair of complementary coils according to an example embodiment of the present disclosure;

FIG. 21 schematically illustrates the simultaneous 3D electric and magnetic field sensing mode of FIG. 12 applied to X, Y and Z directions according to an example embodiment of the present disclosure;

FIG. 22 is a plan view of an array of dual-pin connectors and of an array of three-pin connectors according to an example embodiment of the present disclosure;

FIG. 23 is a perspective view of the two-pin connector of FIG. 18 according to an example embodiment of the present disclosure;

FIG. 24 is a perspective cross-section view of the dual pin connector of FIG. 23;

FIG. 25 shows top and front views of the dual pin connector of FIG. 23;

FIG. 26 shows bottom and side views of the dual pin connector of FIG. 23;

FIG. 27 is a perspective view of a three-pin connector of FIG. 19 according to an example embodiment of the present disclosure;

FIG. 28 is a perspective cross-section view of the three-pin connector of FIG. 27;

FIG. 29 shows top and front views of the three-pin connector of FIG. 27;

FIG. 30 is a side view of the three-pin connector of FIG. 27;

FIG. 31 illustrates an q-pin connector with adaptive-tuner and automatic impedance matching according to an example embodiment of the present disclosure;

FIG. 32 illustrates a connector-to-connector wireless communications system according to an example embodiment of the present disclosure;

FIG. 33 illustrates a connector-to-connector wireless communications system according to another example embodiment of the present disclosure;

FIG. 34 illustrates a smart control module of the connector-to-connector wireless communications system of FIG. 32 in more detail;

FIG. 35 illustrates a multiple-inputs-multiple-outputs (MIMO) system according to an example embodiment of the present disclosure;

FIG. 36 illustrates a calibration configuration of MIMO systems according to an example embodiment of the present disclosure;

FIG. 37 schematically illustrates MIMO connectorized links for interfacing Front-End-Modules to low-loss polymer waveguides according to an example embodiment of the present disclosure;

FIG. 38 schematically illustrates MIMO systems in TX and RX for interfacing 3D Probes/Antennas to polymer-based waveguiding structures;

FIG. 39 illustrates mosaic-partitioning MIMO systems using multi-pin connectors for scalable large-array solutions;

FIG. 40 is a perspective view of an RDL/RDV (Re-Distribution-Layer/Re-Distribution-Volume) solution;

FIG. 41 is a cross-section view of the RDL/RDV solution of FIG. 40;

FIG. 42 to 44 are plan view of arrays of SMPM (Sub-Miniature Push-on Micro) connectors according to example embodiments of the present disclosure;

FIG. 45 schematically represents an assembly of 1024 MIMO systems built using 32×32 unitary elements composed of 4×4 Mosaic-cells with 8×8 elements each, according to an example embodiment of the present disclosure;

FIG. 46 is a perspective view of the assembly of FIG. 45 comprising electric, magnetic, energy-density (combined Electric and Magnetic) probing solutions according to an example embodiment of the present disclosure; and

FIG. 47 schematically illustrates a liner-array partitioning solution.

### DESCRIPTION OF EMBODIMENTS

Like features have been designated by like references in the various figures. In particular, the structural and/or functional features that are common among the various embodiments may have the same references and may dispose identical structural, dimensional and material properties.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

### First Aspect—Electric/Magnetic Field Probe

In the following description, reference is made to probes comprising coils for detecting electric and magnetic fields. However, rather than coils, more generally sensor element could be used that is sensitive to electric and magnetic fields. For example, types of self-inductance having a form other than a coil could be employed.

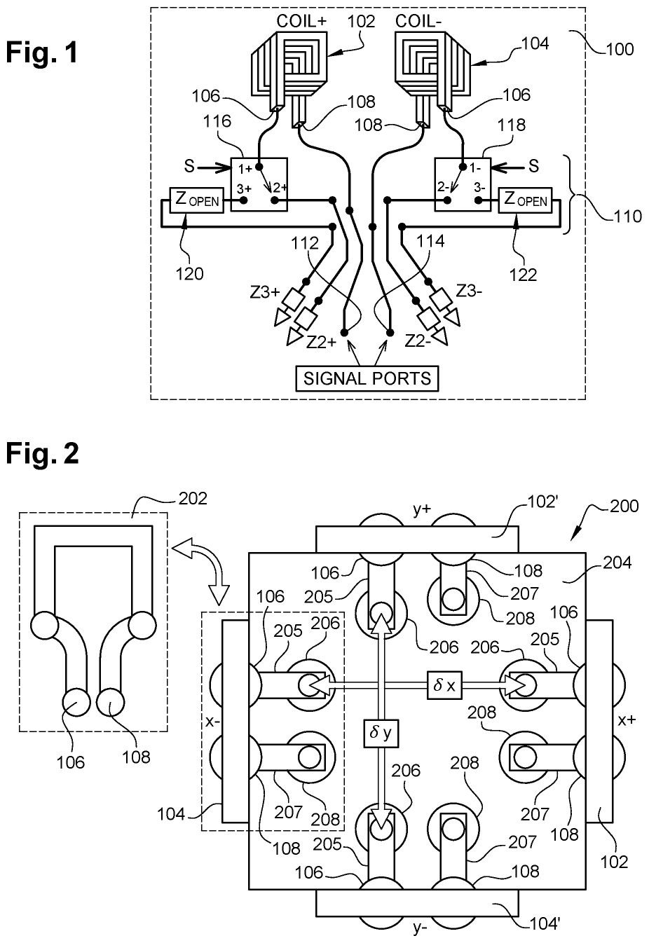

FIG. 1 schematically illustrates an electric/magnetic field probe 100 according to an embodiment of the present disclosure. The probe 100 for example comprises coils 102 (COIL+) and 104 (COIL−), which are for example complementary coils in that they are orientated in opposite directions from each other, and configured to measure opposite fields +/−. For example, the coil 102 is configured to measure a positive field in an x, y or z direction, and the coil 104 is configured to measure a negative field in the same x, y or z direction. For example, the coils 102, 104 are for example positioned on opposite sides of the probe 100, such that an average of the signals sensed by the coils 102, 104 permits the electric and magnetic fields at the center of the probe to be determined. Each coil 102, 104 for example has a first terminal 106 at one end of the coil, and a second terminal 108 at the other end of the coil.

The terminals 106 of the coils 102, 104 are for example coupled to a switching circuit 110. The terminals 108 of the coils 102, 104 are for example coupled to output signal ports (SIGNAL PORTS) 112, 114 respectively of the probe 100.

The switching circuit 110 for example comprises switches 116, 118, which are each for example single port, double throw (SPDT) switches. In alternative embodiments, the switches could be implemented in silicon, for example using CMOS technology. The switches 116, 118 are for example each controlled by a control signal S. The switch 116 is for example capable of connecting the terminal 106 of the coil 102, which is coupled to an input 1+ of the switch 116, to either an impedance Z2+ coupled to an output terminal 2+ of the switch 116, the impedance Z2+ being coupled in turn to ground, or to an open circuit impedance (Z_OPEN) 120 coupled to an output terminal 3+ of the switch 116, the impedance 120 for example being coupled to ground via an impedance Z3+. Similarly, the switch 118 is for example capable of connecting the terminal 106 of the coil 104, which is coupled to an input 1+ of the switch 118, to either an impedance Z2− coupled to an output terminal 2− of the switch 118, the impedance Z2− being coupled in turn to ground, or to an open circuit impedance (Z_OPEN) 122 coupled to an output terminal 3− of the switch 118, the impedance 122 for example being coupled to ground via an impedance Z3−. The impedances Z2+, Z2−, Z3+, Z3− are for example used to isolate the terminals in a PCB implementation, and are for example arranged to have a mutual impedance of less than 0.1 pH. The open-circuit impedances 120 are for example of at least 1M ohms, and for example of at least 100M ohms, and in some cases greater than 1G ohms. The impedances Z2+ and Z2− are for example of less than 10 pH.

In some embodiments, the coils 102 and 104 are each dimensioned to receive frequencies of at least 1 GHz, and for example of at least 30 GHz. For example, the one or more loops or turns of each coil 102 and 104 have a diameter of around 1 mm, for example of between 0.7 mm and 3 mm, depending on the frequency range to be detected.

In operation, the control signal S, which is for example generated by a control circuit external to the probe 100, can be used to switch the probe 100 between an electric field sensing mode and a magnetic field sensing mode. In particular, when the switches 116 and 118 are controlled by the signal S to couple the terminals 106 of the coils 102, 104 to the impedances Z2+, Z2−, the signals present at the signal ports 112, 114 provide magnetic field measurements. In particular, current generated in the coils 102, 104 can for example be averaged in order to estimate the magnetic field at the center of the probe 100. When the switches 16, 118 are controlled by the signal S to couple the terminals 106 of the coils 102, 104 to the open-circuit impedances 120, 122 respectively, the coils 102, 104 form dipole antennas, and the signals present at the signal ports 112, 114 provide electric field measurements. In the case of stochastic fields, or relatively slowly changing fields, the probe 100 can be switched between the electric field sensing and magnetic field sensing modes such that the power density and/or energy density can be determined. The switches 116, 118 are for example capable of being switched at periods of 1 ns or less, corresponding to frequencies of 1 GHz or more.

An advantage of the energy probe of FIG. 1 is that the controllable high-impedance and low-impedance branches permit a same hardware layout to be used for simultaneous magnetic and electric field sensing.

FIG. 2 is a plan view of a coil module 200 of an X and Y electric/magnetic field probe according to an embodiment of the present disclosure. The coil module 200 for example comprises four coils permitting 2D field sensing. For example, the coil module 200 comprises the complementary coils 102, 104 of the probe of FIG. 1 configured to detect fields in the x+ and x− directions, and similar complementary coils 102′, 104′ that are configured to detect fields in the y+ and y− directions. In the example of FIG. 2, the coils are implemented by a single wire loop, although other implementations would be possible. The coils 102, 104 are for example mounted at two opposite edges of a rectangular or square substrate 204, which is for example a PCB (printed circuit board). The coils 102′, 104′ are also for example mounted at the other two opposite edges of the substrate 204. The terminal 106 of each coil 102, 104, 102′, 104′ is for example coupled via a corresponding track 205, formed on the surface of the substrate, to a corresponding pad 206. Similarly, the terminal 108 of each coil 102, 104, 102′, 104′ is for example coupled via a corresponding track 207, formed on the surface of the substrate, to a corresponding pad 208. The pads 206 and 208 are for example used to couple the coil module to a PCB. The pads 206 coupled to the coils 102, 104 are for example separated by a distance δₓ of at least 80 μm and for example of less than 5 mm. Similarly, the coils 102′, 104′ are for example separated by a distance δ_{y} of at least 80 μm and for example of less than 5 mm. An isolation between the pads is for example of at least −30 dB.

In the case that the coil module 200 is implemented in silicon, the pads 206, 208 are for example implemented by BGA (Ball Grid Array) bumps.

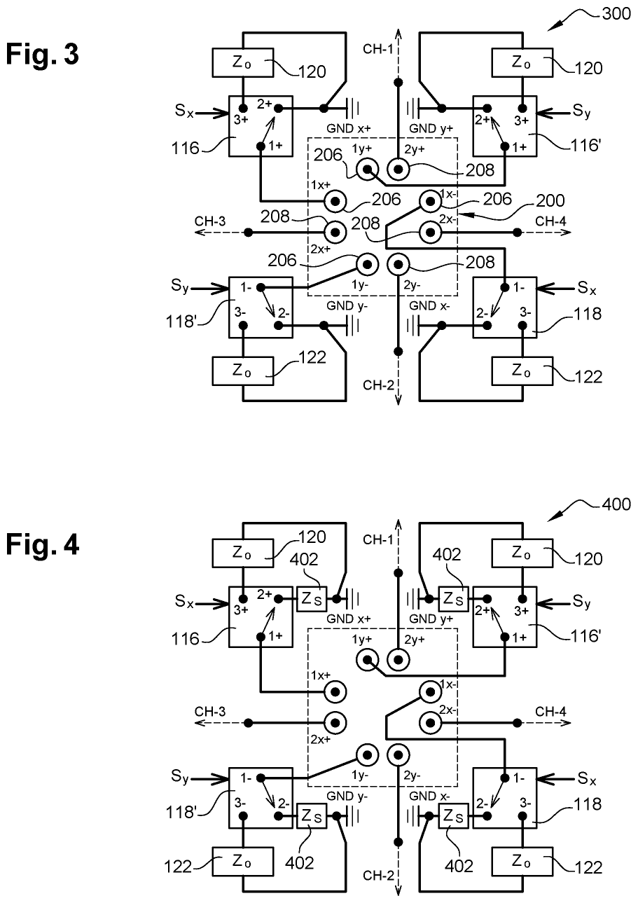

FIG. 3 schematically represents an x and y electric/magnetic field probe 300 comprising the coil module 200 of FIG. 2, and a switching circuit comprising the switches 116 and 118 controlled by a signal Sx, and similar switches 116′ and 118′ controlled by a signal Sy. The control signals Sx and Sy respectively control when the x-direction and y-direction coils detect electric and magnetic fields. The switches 116, 118, 116′, 118′ are for example coupled to the vias 206, and the vias 208 are for example coupled to output channels CH-1, CH-2, CH-3 and CH-4 of the probe 100. In the example of FIG. 3, the impedances Z2+, Z3+, Z2− and Z3− are omitted, and the terminals 2+ and 2− of the switches 116, 116′, 118, 118′ are connected directly to a ground rail (GND), and the terminals 2+ and 2− of the switches 116, 116′, 118, 118′ are connected to the ground rail via the impedance 120 or 122 having a same impedance Zo. In some embodiment, to improve isolation between the channels, there is separate power supply per channel, and thus a ground rail per channel, these rails being labelled GNDx+, GNDx−, GNDy+ and GNDy− in FIG. 3.

In some embodiments, the switches 116, 116, 118, 118′ are controlled output of phase with each other, for example the switches being controlled to capture electric and magnetic fields using the channels x+ and x− during a first phase, and the switches being controlled to capture electric and magnetic fields using the channels y+ and y− during a second phase. This can help improve isolation between the x and y channels.

FIG. 4 schematically represents an x and y electric/magnetic field probe 400 that is similar to the probe 300 of FIG. 3, but additionally comprises the impedances Zs 402 coupling the terminals 2+ and 2− of the switches 116, 116′, 118, and 118′ to the ground rail (GND).

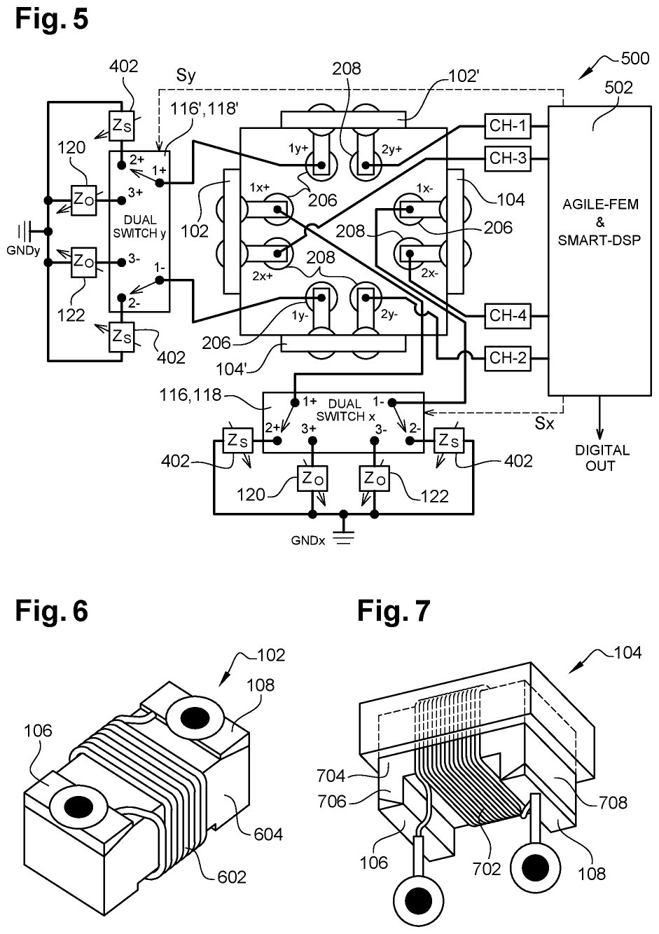

FIG. 5 schematically represents an x and y electric/magnetic field probe 500 comprising the coil module of FIG. 2 according to an alternative embodiment to those of FIGS. 3 and 4, and front-end module and digital signal processor (AGILE-FEM & SMART DSP) 502. The probe 500 is similar to the probe 400 of FIG. 4, except that the impedances 120, 122 and 402 are variable impedances, allowing them to be tuned, for example by the front-end module 502. Furthermore, the switches 116 and 118 are implemented by a dual switch (DUAL SWITCH) incorporating the functionality of two SPDT switches, and similarly the switches 116′ and 118′ are implemented by a dual switch (DUAL SWITCH). An advantage of using dual switches is that an improved synchronization between the switching of each switch of the dual switch is obtained.

The front-end module and DSP 502 is for example configured to generate the control signal Sy and Sx for controlling the switches 116, 118 and the switches 116′, 118′ respectively. Furthermore, the front-end module 502 for example receives the output signals CH-1, CH-2, CH-3 and CH-4 from the coils, and performs digital signal processing on the signals, in order to provide one or more output signals (DIGITAL OUT). For example, the front-end module and DSP 502 comprises one or more analog to digital converters for converting the signals on the channels CH-1, CH-2, CH-3 and CH-4 into digital signal. Furthermore, in some embodiments, the front-end module 502 may transform the signals from each channel from the time domain into the frequency domain, and/or perform other signal processing and/or signal conditioning on the output signals of the probe 500.

FIG. 6 is a perspective view of a device implementing the coil 102 of the electric/magnetic field probe 100 of FIG. 1 according to one example. The device 102 is for example an SMD (surface mounted device), comprising a wire 602 coiled clockwise around a body 604 in the form of a rectangular block, formed of an insulating material. The wire 602 for example comprises in insulating coating, and is soldered at each end to the terminals 106, 108, formed by metal coating at the extremities of the body 604. The coil 104 is for example implemented by a similar device, but with the wire 602 forming anti-clockwise turns.

FIG. 7 is a perspective view of a device implementing the coil 104 of the electric/magnetic field probe 100 of FIG. 1 according to an alternative example to that of FIG. 1. The device 104 for example comprises a wire 702 coiled anti-clockwise around a body 704 in the form of a rectangular block, formed of an insulating material, and having a foot 706, 708 extending from each extremity. The wire 602 for example comprises in insulating coating, and is soldered at each end to the terminals 106, 108, which in the example of FIG. 7 are formed by metal plates on undersides of the feet 706, 708 respectively. The coil 102 can for example be implemented by a similar device, but with the wire 602 forming clockwise turns.

Of course, FIGS. 6 and 7 provide merely two examples of devices implementing the coils, many other implementations being possible, including implementations in which the wire forms only a partial turn between the terminals 106 and 108. For example, rather than being formed as SMDs, in alternative embodiments the coils 102 and 104 are formed in WLCSP (wafer-level-chip-scale-packaging) technology.

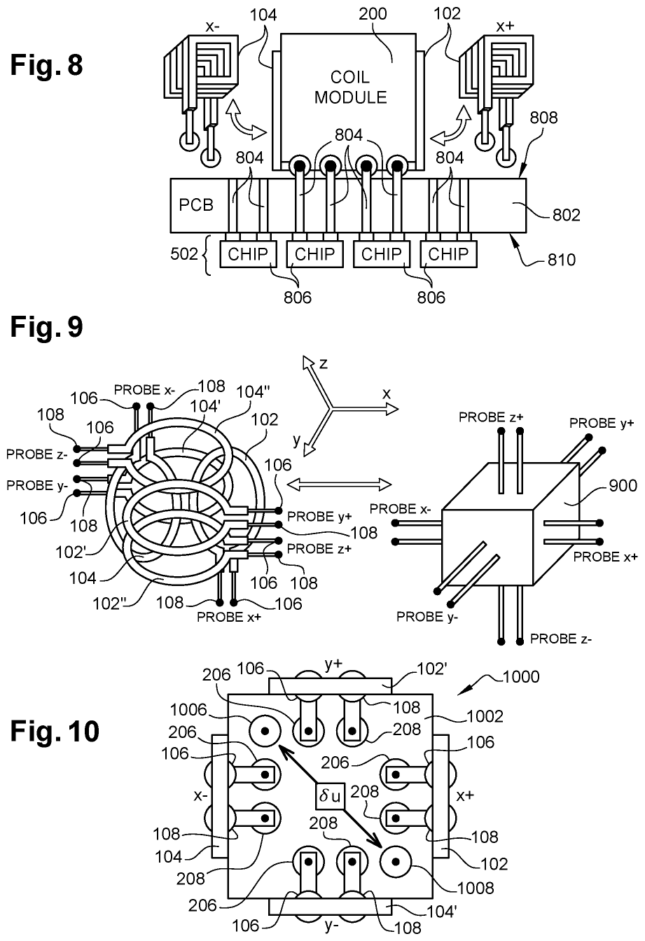

FIG. 8 is a cross-section view schematically illustrating a sensing device 800 comprising the coil module (COIL MODULE) 200 of FIG. 2, mounted on a substrate 802, for example implemented by a PCB. Vias 804 for example traverse the PCB 802, connecting outputs of the coil module 200 to chips (CHIPS) 806, which for example implement the front-end module 502. For example, the coil module 200 is mounted on a top surface 808 of the PCB 802, and the chips 806 are mounted on a bottom surface 810 of the PCB, the top and bottom surfaces 808, 810 being opposite surfaces.

While the embodiments described above relate to 2D probes having one or two detection directions, examples of a 3D probe having x, y and z detection directions will now be described in more detail with reference to FIGS. 9 to 12.

FIG. 9 schematically illustrates an electric/magnetic field sensing probe 900 capable of sensing electric and magnetic fields in x, y and z directions according to an example embodiment of the present disclosure. As represented on the left in FIG. 9, the probe for example comprises three pairs of complementary coils 102 and 104, 102′ and 104′, 102″ and 104″, arranged respectively in x, y and z directions, the coils 102, 102′ and 102″ detecting positive fields, and the coils 104, 104′ and 104″ detecting negative fields. Each coil has terminals 106, 108.

As represented on the right-hand side of FIG. 9, the probe 900 for example six pairs of connections to the terminals 106, 108 of each coil, labelled as probes x+, x−, y+, y−, z+, z−.

FIG. 10 is a plan view of a coil module 1000 of an x, y and z electric/magnetic field probe, such as the probe 900 of FIG. 9, according to an embodiment of the present disclosure. The coil module 1000 is similar to the coil module 200 of FIG. 2, and like features have been labelled with like reference numerals and will not be described again in detail. The coil module 1000 additionally comprises pads 1006, 1008, which are for example used to couple the coil 102″ in the z direction. The coil 104″ is for example implemented in the PCB 802 of FIG. 8. Alternatively, only the coil 102″ is present in the z direction, and the average z values can be deduced from this reading combined with the reading from the other x and y channels.

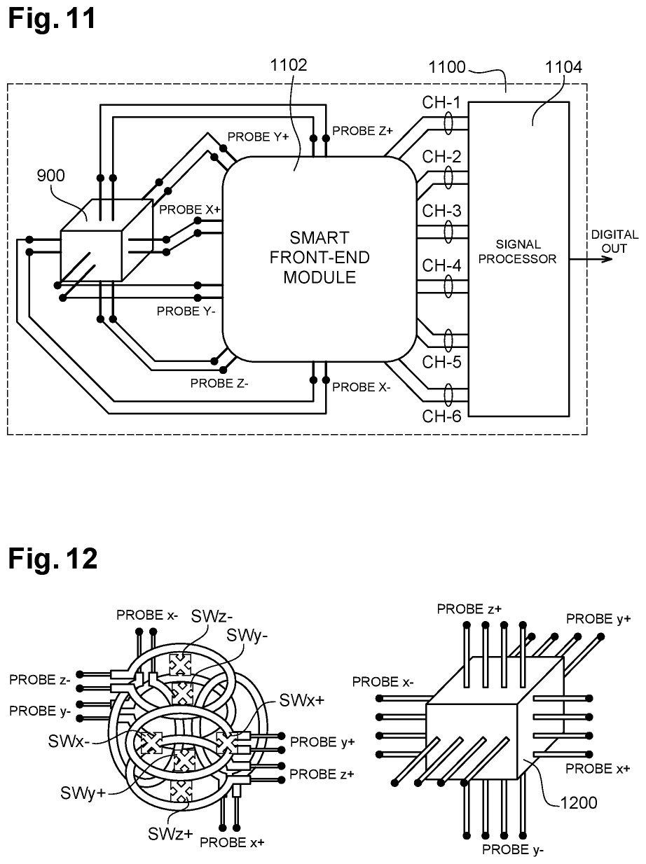

FIG. 11 schematically illustrates a sensing device 1100 for electric/magnetic field sensing in x, y and z, according to an example embodiment. The sensing device 1100 comprises the electric/magnetic field sensing probe 900 of FIG. 9, as well as a front-end module (SMART FRONT-END MODULE) 1102, which for example performs a similar role to the front-end module 502 of FIG. 5. However, in the embodiment of FIG. 11, rather than comprising switches for coupling a terminal of each coil to ground or a high impedance, the front-end module 1102 is configured to sense signals present at both terminals of each coil. For example, the magnetic field can be determined by detecting a current between the terminals, and the electric field can be determined by measuring the voltage across each coil. Thus, the front-end module 1102 is configured to receive and process pairs of output signals PROBE X+, PROBE X−, PROBE Y+, PROBE Y−, PROBE Z+ and PROBE Z− from the probe 900, and to generate corresponding output channels CH-1 to CH-6 each comprising the pair of signals from the corresponding coil. The device 1100 also for example comprises a signal processor (SIGNAL PROCESSOR) 1104, which is for example a DSP (Digital Signal Processor), and generates one or more digital outputs (DIGITAL OUT). The signal processor 1104 for example comprises analog to digital converters for converting the signals from the front-end module 1102 into digital signals. In some embodiments, the signal processor 1104 is further configured to transform the signals from each channel from the time domain into the frequency domain, and/or perform other signal processing and/or signal conditioning on the output signals of the front-end module 1102.

In alternative embodiments, the front-end module 1102 could be a switched front-end module comprising switches 116, 118 and 116′, 118′ as described above for the x and y channels, and similar switches 116″, 118″ (not illustrated) for the z channels. In such a case, only six signals, rather than twelve, are for example provided from the front-end module 1102 to the DSP 1104, one signal per channel CH-1 to CH-6.

FIG. 12 schematically illustrates an electric/magnetic field sensing probe capable of sensing electric and magnetic fields in x, y and z directions and further comprising spin-wave detectors according to an example embodiment of the present disclosure. In particular, in the embodiment of FIG. 12, a pair of complementary spin-wave detectors is orientated in each direction, and configured to receive signals of opposite polarization. For each, spin-wave sensors SWx+, SWy+ and SWz+ are orientated in the x, y and z directions respectively, and are configured to receive X-polarized signals. Spin-wave sensors SWx−, SWy− and SWz− are orientated in the x, y and z directions respectively, and are configured to receive Y-polarized signals.

In some embodiments, rather than providing the spin-wave sensors in addition to the coils, the spin-wave sensors replace the coils, and form sensing elements that can be used to detect magnetic and electric fields.

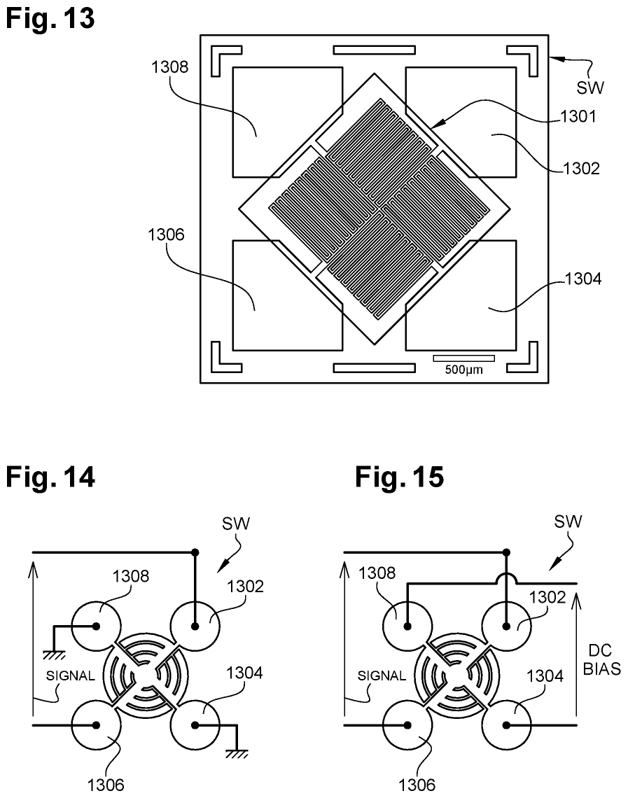

FIG. 13 is a top view of one of the spin-wave sensors SW of FIG. 12 according to an example embodiment of the present disclosure.

The spin-wave sensor SW for example has a substantially square footprint, and width of between 1 and 10 mm, although other shapes and dimensions would be possible. In the example of FIG. 13, the spin wave sensor SW has a width of around 2.5 mm. The example of FIG. 13 is based on a spin-wave sensor SW having a closed detection loop 1301, and four contact pads corresponding to the terminals 1302, 1304, 1306, 1308 of the closed detection loop 1301 are visible on the top surface of the spin-wave sensor SW, close to its respective corners.

FIG. 13 illustrates one possible patterning of the closed detection loop 1301. In particular, the loop 1301 is for example formed over a square-shaped area which is positioned in the middle of the spin-wave sensor SW orientated at an angle of 45 degrees with respect to the edges of the sensor. The detection loop 1301 for example comprises, in each quadrant of its area, a serpentine pattern, adjacent quadrants having serpentines running perpendicular to each other, and diagonally opposing quadrants having serpentines running the same direction as each other. A point of the detection loop between each of the adjacent quadrants is connected to a corresponding one of the terminals 1302, 1304, 1306, 1308. Of course, other patterns of the detection loop 1301 would be possible, such as the one described in the patent application published as EP3208627 or in PCT application PCT/EP2020/082141 filed on 13 Nov. 2020.

FIG. 14 schematically illustrates the spin-wave sensor SW according to an example in which it is referenced to ground, in other words the terminals 1304 and 1308 being coupled to ground rails, and the terminals 1302 and 1306 providing an output signal (SIGNAL) of the sensor.

FIG. 15 schematically illustrates the spin-wave sensor SW according to another example in which it is biased by a DC voltage, in other words the contacts 1304 and 1308 receiving a DC biasing voltage (DC BIAS), and the contacts 1302 and 1306 providing an output signal (SIGNAL) of the sensor.

### Second Aspect—MIMO Smart Connectors

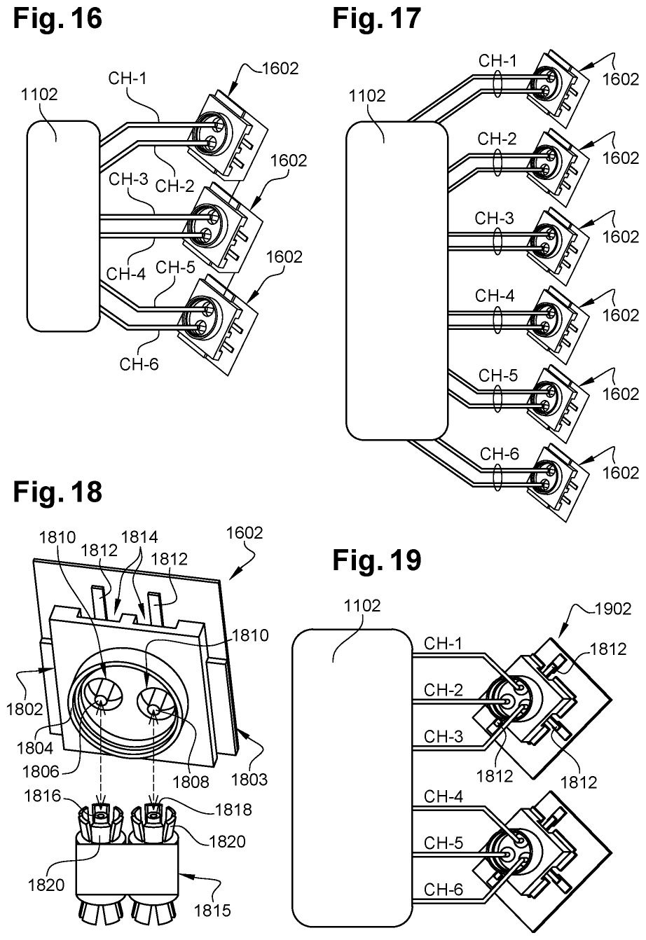

For cases in which the probes described above are used to measure signals at relatively high frequencies, for example of at least 1 GHz, isolation to avoid interference between the channels is of particular importance. Furthermore, in some cases it may be desired to provide an array of probes coupled to an interface board such as a MIMO (multiple-input multiple-output) interface. However, standard connectors are relatively bulky for such applications, and/or do not provide adequate isolation. Connector solutions having advantages in terms of compactness and electromagnetic isolation will now be described in more detail with reference to FIGS. 16 to 31.

FIG. 16 schematically illustrates the front-end module 1102 of FIG. 11 in more detail in the case that it is a two-pin based six port switched front end module. In particular, it provides six output channels CH-1 to CH-6, each on a corresponding wire, which are for example coupled to other circuitry, such as the signal processor 1104 of FIG. 11, via two-pin connectors 1602. Each channel CH-1 to CH-6 is for example transmitted on a single wire, the front-end module 1102 for example comprising switches for coupling one of the terminals of each coil to an open-circuit impedance or to a ground rail. For example, the wires with the channels CH-1 and CH-2 are coupled to the two pins of a first of the connectors 1602, the wires with the channels CH-3 and CH-4 are coupled to the two pins of a second of the connectors 1602, and the wires with the channels CH-5 and CH-6 are coupled to the two pins of a third of the connectors 1602.

FIG. 17 schematically illustrates a front-end module 1102 of FIG. 11 in more detail in the case that it is a dual-pin based six port switched front end module. In particular, it provides six output channels CH-1 to CH-6, each on a pair of corresponding wires, which are for example coupled to other circuitry, such as the signal processor 1104 of FIG. 11, via two-pin connectors 1602, one per channel. The front-end module 1102 does not for example comprise any switches, and couples both of the terminals of each coil to the corresponding pair of wires.

FIG. 18 is a perspective view of the two-pin connector 1602 of FIGS. 16 and 17. The connector 1602 comprises a connector body 1802, for example in the form of a rectangular block, which is for example mounted on a substrate 1803, such as a PCB. The connector body 1802 is example formed of metal, and comprises a metallic shielding tube 1804 extending from its top surface, which is the surface opposite to one in contact with the substrate 1803. The pins 1806 and 1808 of the connector for example extend through holes 1810 that pass through the connector body 1802, the holes 1810 being positioned in a portion of the connector body 1802 that is within the shielding tube 1804. The holes 1810 are for example circular, although other shapes would be possible, and the pins 1806, 1808 are for example centrally positioned in each hole 1810. For example, each pin 1806, 1808 is separated from the inside surface of its through-hole 1810 by a separation of at least 0.1 mm. Each pin 1806, 1808 for example has a diameter of between 0.1 and 1 mm.

The pins 1806, 1808 are for example fixed, for example with solder, or using a mechanical joint such as a threaded joint, two corresponding metal tracks 1812, which exit one side of the body 1802. For example, the body 1802 comprises tunnels 1814, via which the metal tracks 1812 emerge. The tunnels 1814 join the respective openings 1810, such that each pin 1806, 1808 and corresponding track 1812 is entirely insulated from the body 1802.

For example, the pins 1806, 1808, the metallic shielding tube 1804, the metal tracks 1812 and/or the connector body 1802 is/are formed of copper, aluminum, or gold.

In some embodiments, the connector 1602 is mounted to the signal processor or other circuit to which the output signals of the front-end module 1102 are to be transmitted, and the connection is made via cables terminating with a two-socket connector 1815, having female sockets 1816, 1818 that respectively connect with the pins 1806, 1808. Each female socket 1816, 1818 is for example in the form of a tube with an inner diameter dimensioned to receive the corresponding pin with a relatively tight fit in order to ensure a good electrical connection. Each female socket 1816, 1816 for example comprises petals 1820 surrounding, and insulated from, the corresponding socket 1816, 1818, the petals being dimensioned to enter into the openings 1810 of the connector 1602 when the female and male portions are engaged together. The petals 1820 are for example formed of metal, and are flexible, such that when pushed into the openings 1810, they are displaced axially towards the sockets 1816, 1818 respectively, but without entering into contact with these parts. In this way, the petals 1820 exert an outward force on inner surfaces of the openings 1810, making a good electrical contact, and maintaining the connectors 1602, 1815 engaged with each other.

While not shown in FIG. 18, the two-socket connector 1815 may also comprise a metallic shielding tube having dimensions such that it engages with the tube 1804 of the connector 1602. For example, the metallic shielding tube of the connector 1815 has an outer diameter that is slightly smaller than an inner diameter of the tube 1804, or the metallic shielding tube of the connector 1815 has an inner diameter that is slightly larger than an outer diameter of the tube 1804. An advantage of providing the metallic shielding tube 1804 in addition to the petals 1820 is that it provides additional electromagnetic shielding for the pair of signals transmitted via the pins 1806, 1808. For example, the signals transmitted via the pins 1806, 1808 are at frequencies that are compatible with each other, for example within a same frequency range, and the shielding tube 1804 acts as a Faraday cage that provides increased isolation against other external frequencies that are more likely to interfere with the signals transmitted over the pins 1806, 1808.

While FIGS. 16 and 17 represent the signals of the channels CH-1 to CH-6 being applied directly to the pins, it will be understood that in practice, the signals are applied to the metal tracks 1812, and the pins 1806, 1808 are used for the transmission of the signals via a corresponding female connector.

FIG. 19 schematically illustrates the front-end module 1102 of FIG. 11 in more detail in the case that it is a three pin-based six-port switched front end module. In particular, it provides six output channels CH-1 to CH-6, each on a corresponding wire, which are for example coupled to other circuitry, such as the signal processor 1104 of FIG. 11, via three-pin connectors 1902. Each channel CH-1 to CH-6 is for example transmitted on a single wire, the front-end module 1102 for example comprising switches for coupling one of the terminals of each coil to an open-circuit impedance or to a ground rail. For example, the wires with the channels CH-1, CH-2 and CH-3 are coupled to the pins of a first of the connectors 1902, and the wires with the channels CH-4, CH-5 and CH-6 are coupled to the two pins of a second of the connectors 1902. The three-pin connectors 1902 are for example similar to the two-pin connectors 1602, except that they comprise three pins positioned in three opening within the metallic shielding tube, and the tracks 1812 for example exit the connector body 1802 on corresponding sides, rather than on a same side.

While FIGS. 16, 17 and 19 illustrate cases in which the front-end module 1102 is coupled to the multi-pin connectors 1602 or 1902 for the purpose of transmitting the signals to further signal processing circuitry, such an arrangement is for example particularly applicable when the probes and front-end module are implemented in silicon as an integrated circuit, such as an ASIC (application-specific integrated circuit). In the case that the probes are implemented separately from the front-end module 1102, like in the example of FIG. 8, the interface between the probes and the substrate (e.g. PCB) is additionally or alternatively implemented by such connectors, the probes comprising male connectors and the PCB comprising female connectors, or vice versa.

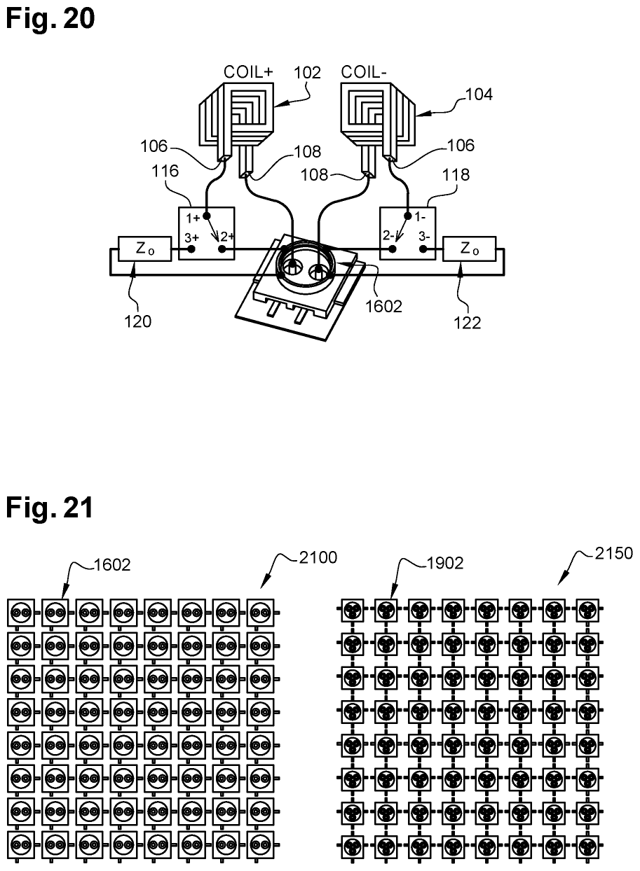

FIG. 20 schematically illustrates the simultaneous 3D electric and magnetic field sensing mode of FIG. 12 applied to X, Y and Z directions according to an example embodiment of the present disclosure. In particular, FIG. 20 illustrate an example arrangement of one of the two-pin connectors 1602 according to an embodiment like that of FIG. 16 in which it is used to transmit signals sensed by the pair of complementary coils 102, 104. In the example FIG. 20, the terminals 2+ and 2− of the switches 116 and 118 are connected to ground via the metallic shielding tube 1602, and the terminals 3+ and 3− of the switches 116 and 118 are connected to ground via the metallic shielding tube 1602 and the open-circuit impedances 120.

In some embodiments, the electric and magnetic field sensing probes described herein are arranged in an array, and are coupled via a corresponding array of the connectors 1602 or connectors 1902 to the signal processing circuitry, as will now be described with reference to FIG. 21.

FIG. 21 illustrates a plan view of an array 2100 of two-pin connectors 1602 according to an example embodiment of the present disclosure. In the example FIG. 21, the array 2100 is an 8 by 8 array, although more generally the array could be an n by m array, where n and m are integers each equal to 2 or more. It would also be possible for the array 2100 to be a linear array. FIG. 21 illustrates a variant of the connectors 1602 in which the metal tracks 1812 exit from different sides the body. In some embodiments, the bodies of the connectors 1602 are electrically connected in order to provide a common ground.

FIG. 21 also illustrates a plan view of an array 2150 of three-pin connectors 1902 according to an example embodiment of the present disclosure. The array 2150 is similar to the array 2100, except that each connector 1602 is replaced by the connector 1902.

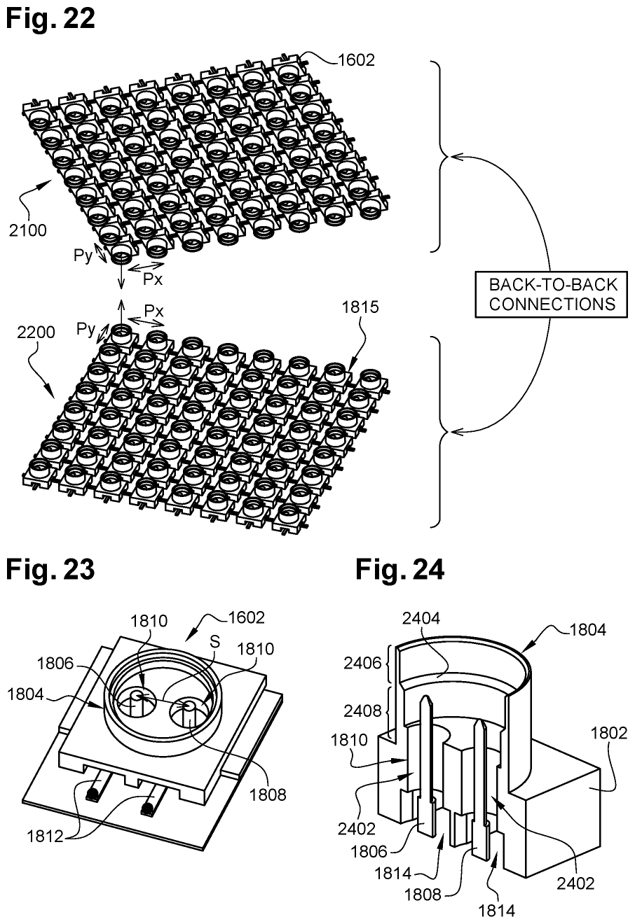

FIG. 22 is a perspective view illustrating an example of how an array of probes can be connected to a signal processing circuit using two arrays of connectors, and without cables. For example, the array 2100 of male connectors 1602 is connected using back-to-back connections (BACK-TO-BACK CONNECTIONS) with a similar array 2200 of female connectors 2150. For example, pitches Px and Py of the connectors in the arrays 2100, 2200 are equal such that each connector 1602 is aligned with a corresponding connector 1815 when the two arrays 2100, 2200 are brought together.

The two-pin connector 1602 is illustrated in more detail in FIGS. 23 to 26.

FIG. 23 is a perspective view of the two-pin connector 1602 according to an example embodiment of the present disclosure. As shown in FIG. 23, a separation distance s between the pins 1806, 1808, which is for example measured between the axe of the pins, is for example of at least 0.5 mm.

FIG. 24 is a perspective cross-section view of the two-pin connector 1602 of FIG. 23. The cross-section passes through the axes of the pins 1806, 1808. It can be seen that the openings 1810 are holes that extend though a portion of the connector body 1802, and join the tunnels 1814. The volume defined by the openings 1810 and tunnels 1814 are for example at least partially filled with an insulating resin 2402. The metallic shielding tube 1804 for example comprises, on its inner surface, a bevel 2404 between an upper portion 2406 and a lower portion 2408, the lower portion 2408 having a smaller inner diameter than the upper portion 2408. The bevel 2404 for example acts as a stop surface for a corresponding shielding tube of the corresponding socket connector 1815 when it is engaged with the connector 1602. This for example protects the pins 1806, 1808 from pressure that could otherwise be exerted on them.

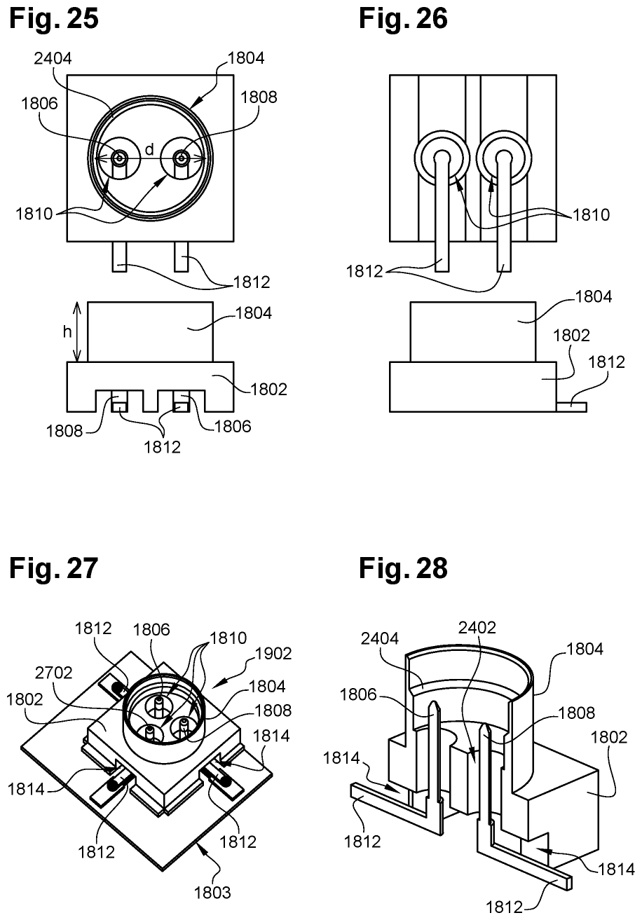

FIG. 25 shows top and front views of the two-pin connector 1602 of FIG. 23. As represented in the top view, the metallic shielding plate 1804 has an inner diameter d, measured in its upper portion 2406, of 10 mm or less. A height h of the metallic shielding tube is for example at least 2 mm, and for example of between 2 and 6 mm.

FIG. 26 shows bottom and side views of the two-pin connector 1602 of FIG. 23.

The three-pin connector 1902 is illustrated in more detail in FIGS. 27 to 30.

FIG. 27 is a perspective view of the three-pin connector 1902 according to an example embodiment of the present disclosure. The three-pin connector 1902 is similar to the two-pin connector 1602, but comprises, in addition to the first and second pins 1806, 1808, a third pin 2702 formed in a further opening 1810 formed in the connector body 1802 within the metallic shielding tube 1804. The third pin 2702 and opening 1810 are for example similar to the other pins 1606, 1608 and opening 1810 as described above. Furthermore, there is an additional conductive track 1812 formed in a further tunnel 1814. The tracks 1812 for example exit the body 1802 on three sides in the example of FIG. 27.

FIG. 28 is a perspective cross-section view of the three-pin connector 1902 of FIG. 27, the cross-section passing through the pins 1806, 1808. The cross-section is similar to the one of FIG. 24, except that the tracks 1812 are visible exiting the tunnels 1814 on opposite sides of the body 1802.

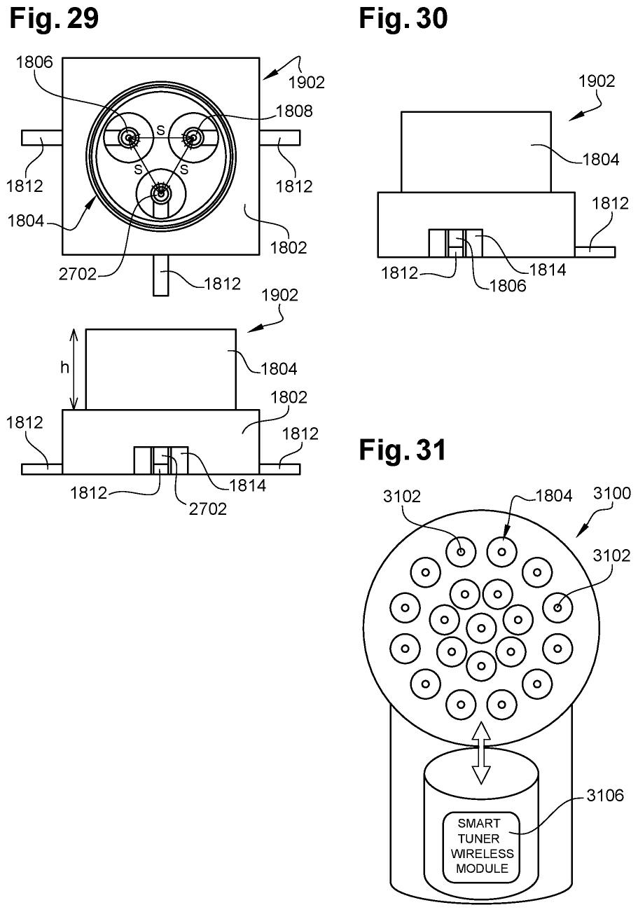

FIG. 29 shows top and front views of the three-pin connector of FIG. 27. Each of the pins 1806, 1808, 2702 is for example separated from the other two pins by a separation distance s equal to at least 0.5 mm.

FIG. 30 is a side view of the three-pin connector 1902 of FIG. 27.

The connectors 1602, 1815 and 1902 as described above can for example be used to make module-to-module connections, such as between front-end modules or between a front-end module and a signal processing module, module to cable connections, such as between a front-end module and a cable, or between a cable and a signal processing module, and/or to implement a connection between a front-end module or cable and one or more of the terminals of the coils 102, 104 described above.

While two-pin and three-pin examples have been described, in alternative embodiments, the connector has a greater number of pins, as will now be described in relation with FIG. 31.

FIG. 31 illustrates an q-pin connector 3100 with adaptive-tuner and automatic impedance matching according to an example embodiment of the present disclosure. In particular, the connector 3100 comprises q pins 3102, where q is for example equal to at least 2, and for example to at least five. Each pin 3102 is for example similar to the pins 1806, 1808 described above, and is centered in a corresponding opening 1804. One or more cables, or a module such as a front-end module or signal processor, can for example be connected to the pins using a female connector comprising q sockets as described in relation with FIG. 18, wherein the sockets are for example arranged in a pattern that is a mirror image of the pattern of the pins 3102, such that the two parts of the connect can be engaged together.

The q-pin connector 3100 for example integrates a tuner wireless module (SMART TUNER WIRELESS MODULE) 3106, that is capable of wireless communicating with other devices for tuning and/or calibration purposes, as will be describe in more detail below.

Third Aspect—MIMO Instruments with Intelligent Probes and Connectors

The automatized testing and validation of devices implementing the latest communications standards, such as 5G (Fifth Generation) and IoT (Internet of Things) communication devices, requires appropriate instruments capable, for example, of evaluating power integrity (PI), signal integrity (SI), and conformity with EMC (Electro-Magnetic Capability) and EMI (Electro-Magnetic Interference) specifications. Indeed, PI, SI, EMC and EMI performance is a critical issue for new generation communications systems that are required to have very high data transmission rates, low energy consummation, and a strong immunity to undesirable disturbances.

Near-field sensing of the emissions of circuits and systems having integrated antennas provides a mechanism to verify EMC/EMI conformity, perform OTA (Over The Air) testing and perform diagnosis of EMC/EMI and power and signal integrity problems.

A solution for such automatized testing and validation can be to use a probe array, such as the array described above, in order to characterize at least part of a DUT (Device Under Test).

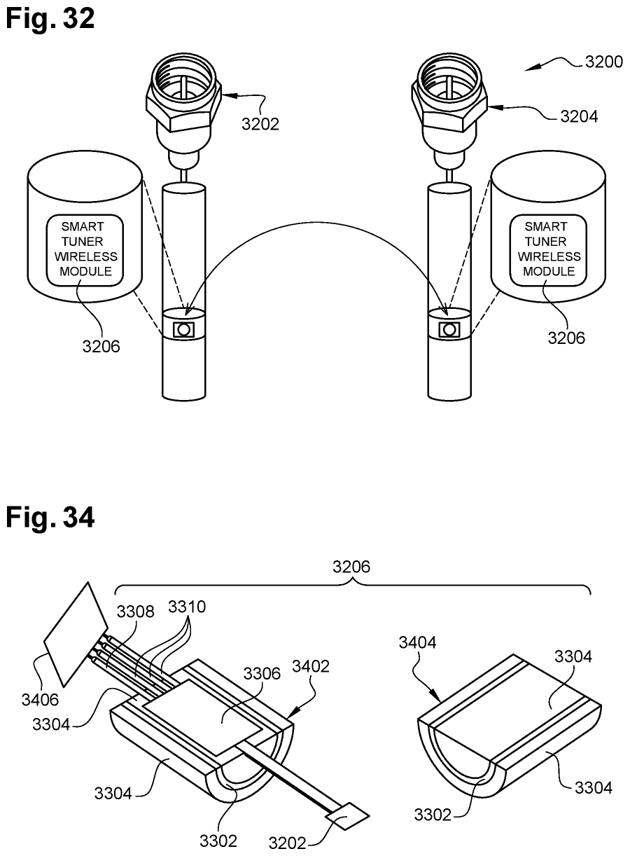

FIG. 32 illustrates a connector-to-connector wireless communications system 3200 suitable for communicating signals captured by one or more probes, from example from one or more probes of a probe array, to a suitable signal processing or test equipment, such as a VNA (vector network analyzer), such as a contactless VNA; and/or an oscilloscope; and/or a spectrum-analyzer. Two connectors 3202, 3204 are illustrated in FIG. 32 as standard co-axial connectors. However, these connectors could equally be implemented by a two-pin, three-pin or q-pin connector as described above. Each connector 3202, 3204 for example comprises a tuner wireless module 3206 (SMART TUNER WIRELESS MODULE). Each module 3206 for example receives one or more signals via its corresponding connector 3202, 3204. Each module 3206 is for example capable of wirelessly transmitting one or more signals to the other module 3206.

For example, the connector 3202 is connected directly to a device under test, and the connector 3204 is connected directly to test equipment, and the wireless modules 3206 permit the wireless transmission of DUT signals from the DUT to the test equipment.

Alternatively, the connector 3202 is connected directly to one or more probes, such as one or more electric/magnetic field probes as described herein, and the connector 3204 is connected directly to test equipment or other signal processing equipment, and the wireless modules 3206 permit the wireless transmission of the probe signals from the probes to the test equipment or signal processing equipment.

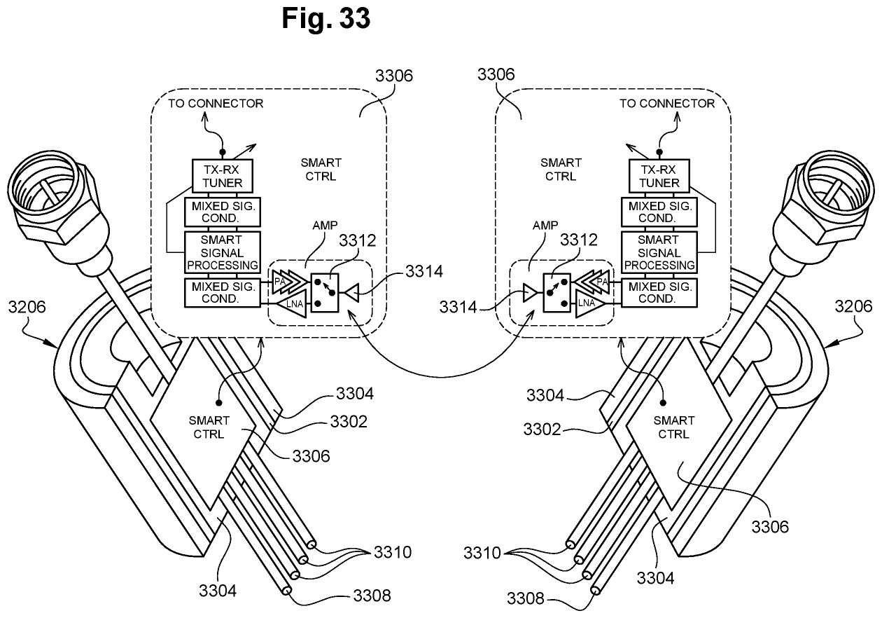

FIG. 33 illustrates the connector-to-connector wireless communications system 3200 of FIG. 32 in more detail according to an example embodiment. FIG. 33 shows the wireless modules 3206 in perspective cross-section view. The modules 3206 are for example capable of being placed in opened and closed configurations. Each module 3206 for example comprises an electrically conductive structure 3302 having, for example, a tubular shape, with a hollow section, for example a circular or a rectangular section, which is prolongated. The electrically conductive structure 3302 is for example obtained by either deposition of a metal or of a conductive material like a polymer or a doped semiconductor, or by a local sintering of a powder or by a conductive tap or glue. The electrically conductive structure 3302 may be a metallic braid. In an example, the electrically conductive structure 3302 has a cross-section width or diameter of at least 300 μm and for example of at least 1 mm. In an example, the electrically conductive structure 3302 is coupled to a ground voltage in order, for example, to provide a robust shield against external radiation. The electrically conductive structure 3302 for example acts as a Faraday cage for any signal passing inside so that the transmission of an RF signal in a wire arranged within the electrically conductive structure 3302 has a transmission noise level as low as −100 dB.

The electrically conductive structure 3302 for example has outer and inner surfaces covered by an insulating layer 3304. In an example, the insulating layer 3304 is formed of a selective laser sintering material, such as nylon or polyamide, or of a spin coated or dipped insulator like polyurethane. The insulating layer 3304 may also be obtained by spraying a dissolved or molten material like a plastic. The insulating layer 3304 may also be obtained by 3D printing, by lamination or by thermal shrinkage.

A control circuit (SMART CTRL) 3306 is for example positioned within the electrically conductive structure 3302 of each module 3206. The circuit 3306 for example comprises a transmission/reception tuner (TX-RX TUNER) coupled to the connector (TO CONNECTOR), and thus configured to receive an input signal of the connector, which is for example an RF signal. The TX-RX tuner is coupled, for example via a mixed-signal conditioning circuit (MIXED SIG. COND.), to a signal processing circuit (SMART SIGNAL PROCESSING), which is in turn coupled, for example via another mixed-signal conditioning circuit (MIXED SIG. COND.) to an amplifier stage (AMP). The mixed signals processed by the circuits for example comprise the RF frequencies and baseband. The amplifier stage for example comprises a power amplifier (PA) for amplifying a signal from the signal processing circuit. An output of the PA is coupled, via a switch 3312 to an antenna 3314 for wireless transmission. A return path from the antenna 3314 is for example provided by the switch 3312 to a low noise amplifier (LNA), which in turn transmits the return signal to the signal processing circuit via the mixed signal conditioning circuit. In this way, two-way communications between the modules 3206 is possible.

In the example of FIG. 33, a conducting wire 3308 is coupled to the control circuit 3306. The wire 3308 is for example embedded in the insulating layer 3304, which reduces the risk of short circuits. The wire 3308 is for example coupled to the control circuit 3306, and provides the circuit 3306 with a supply voltage. One or more further wires 3310 (three in the example of FIG. 33) also for example extend through the insulating layer 3304 within the electrically conductive structure 3302, and are coupled to the control circuit 3306. These conducting wires 3310 for example respectively supply one or more control signals and/or reset signals and/or biasing signals to the control circuit 3306.

FIG. 34 illustrates one of the wireless module 3206 of the connector-to-connector wireless communications system 3200 of FIG. 32 in more detail, in cross-section view. Signals to the wires 3308, 3310 are for example provided by a circuit 3406. The electrically conductive structure 3302 and the insulating layer 3304 are for example formed of at least a first and a second portion 3402, 3404. In a closed configuration, the first and second portions 3302, 3304 are attached together. In an opened configuration illustrated in FIG. 34, the first and second portions 3402, 3404 are separated in such a way that the control circuit 3306 is accessible. In an example, the first and second portions 3402, 3404 comprise a layer of a magnetic material for holding the portions together when in the closed configuration. In another example, rather than a layer of magnetic material, a clip could be used to fix together the first and second portions 3402, 3404 when in the closed configuration.

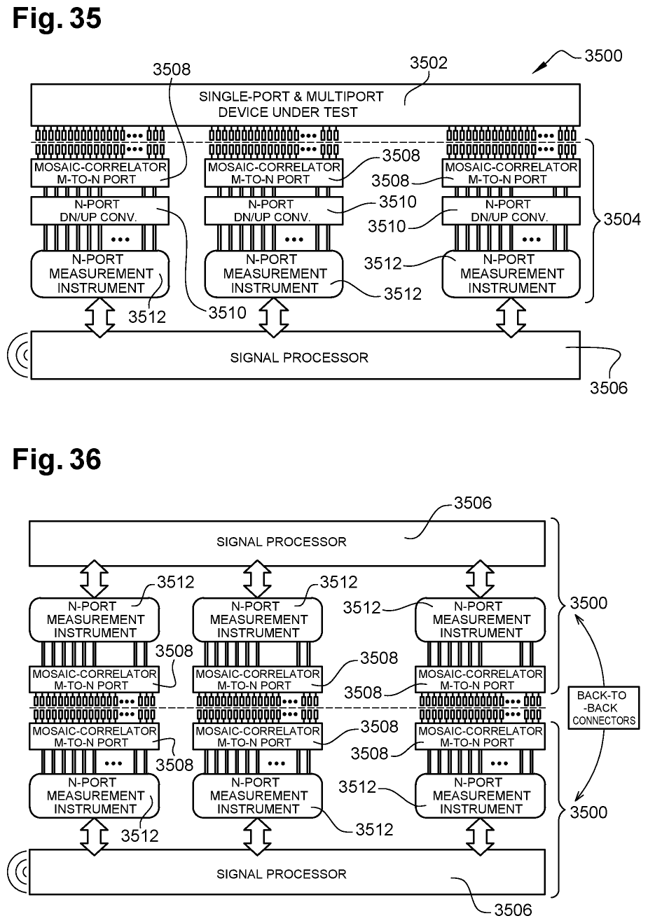

In some embodiments, the wireless connectors of FIGS. 32 to 34 are used within a MIMO (Multiple-Inputs Multiple-Outputs) system, as will now be described in more detail with reference to FIGS. 35 and 36.

FIG. 35 illustrates a modular MIMO system 3500 according to an example embodiment of the present disclosure. The MIMO system is for example used to couple a device under test (SINGLE-PORT & MULTIPORT DEVICE UNDER TEST) 3502, or a probe array, to a signal processor (SIGNAL PROCESSOR) 3506, which is for example a smart co-array signal-processing and synchronization circuit that includes the capacity to perform port-to-port correlations, in other words to select two or more of the ports of the DUT to which a correlation calculation is to be applied. The DUT 3502 for example comprises a multiple of M ports, each port for example being capable of receiving an input signal having a frequency of between 50 and 120 GHz. MIMO circuitry 3504 between the DUT 3502 and the signal processor 3506 for example comprises one or more parallel implementations of an M-to-N mosaic correlator (MOSAIC-CORRELATOR M-TO-N PORT) 3508, an N-port down/up converter (N-PORT DN/UP CONV.) 3510, and an N-port measurement instrument (N-PORT MEASUREMENT INSTRUMENT) 3512.

The mosaic correlator 3508 corresponds for example to an ASIC (Application-Specific Integrated Circuit) correlator as described in the publication entitled “Cognitive Beamformer Chips with Smart-Antennas for 5G and Beyond: Holistic RFSOI Technology Solutions including ASIC Correlators”, S. Wane et al. For example, M input ports of the mosaic correlator 3508 are coupled to the M ports of the DUT, for example via wireless connectors and/or via connectors as described herein.

N output ports of the mosaic correlator 3508 are for example coupled to the N-port up/down converter 3510, which is for example configured to perform frequency conversion.

N outputs of the converter 3510 are for example coupled to the N-port measurement instrument 3512, the output of which is for example coupled to the signal processor 3506. For example, the instrument 3512 is a time-domain oscilloscope or vector network analyzer (VNA).

In some embodiments, multiple parallel units formed of the mosaic correlator 3508 and N-port converter 3510, and N-port measurement circuit 3512 are provided, depending on the number of ports of the DUT. This has the advantage that, in case of a fault effecting one of the units, only this unit can be replaced. For example, if a socket on one of the correlators 3508 becomes faulty, only this correlator 3508 can be replaced, without replacing all of the correlators.

For example, the signal processor 3506 is capable of wireless communications.

MIMO systems are for example described in more detail in the international patent application published as WO2021/123447, the contents of which is hereby incorporated by reference.

FIG. 36 illustrates a calibration configuration of MIMO systems of FIG. 35 according to an example embodiment of the present disclosure. As illustrated, for calibration purposes, two such MIMO systems can be couple back-to-back via connectors (BACK-TO-BACK CONNECTORS), and the signal processors 3506 used to calibrate each MIMO system.

A method of determining calibration parameters of the instrument interface device of FIG. 35 for example comprises providing two of the instrument interface devices arranged back-to-back, and coupling the connector of each instrument interface device to co-array signal-processing and synchronization equipment. For example, the signal processors 3500 are each configured to perform a test phase to test the properties of the connectors of the other. This involves transmitting test signals from one signal processor 3506 to the other via the interface, and tested by the other signal processor whether expected amounts of attenuation are observed. Thus, the signal processor 3506 is for example configured to determine at least a voltage offset and/or a phase offset introduced by the instrument interface device and/or by the DUT interface device.

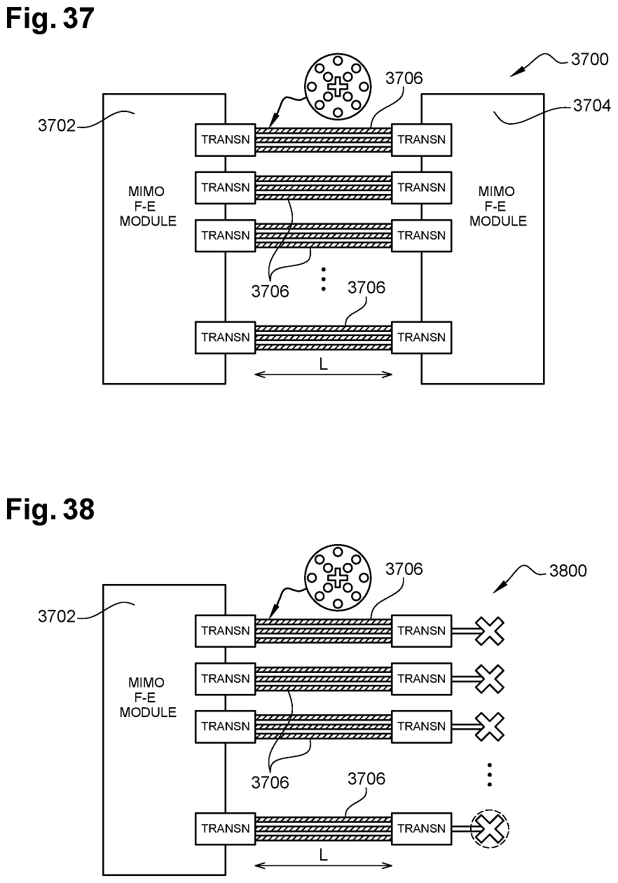

FIG. 37 schematically illustrate a MIMO system 3700 comprising MIMO connectorized links for interfacing front-end modules 3702, 3704 in transmission and reception using one or more low-loss polymer waveguides 3706 according to an example embodiment of the present disclosure. For example, FIG. 37 illustrates smart-connectors with low-loss polymer-waveguiding for RF/mmWave MIMO systems in RX and TX. The arrangement of FIG. 37 is for example used for calibration like in the arrangement of FIG. 36. The interface between the front-end modules 3702 and 3704 with the waveguides 3706 are for example performed using the multi-pin connectors as described herein, and 3D transitions (TRANSN) that comprise a taper for progressively interfacing the metal pin of the multi-pin connector with the waveguides. The low-loss polymer waveguiding technologies are based on the solutions presented by S. Wane and N. Aflakian in the publication entitled “Photonics Chip-to-Chip Communication for Emerging Technologies: Requirements for Unified RF, mmWaves and Optical Sensing”, IEEE Texas Symposium on Wireless and Microwave Circuits and Systems, 2019. A length L of each waveguide is for example in the range 10 mm to 1 m or more. In some embodiments, the length is equal to at least the wavelength λ of the signal to ne transmitted, such that coupling between the circuits can be prevented. As represented by a cross-section in FIG. 37, each waveguide 3706 for example comprises at least two waveguides (represented by circles) for example implemented by hollow tunnels extending through a waveguide material, which is for example polymer based. In some embodiments the waveguides are circular in cross-section, although other forms would be possible. In some embodiments, a number w of waveguides in each waveguide 3706 is equal to the number q of pins in the multi-pin connectors used to interface with the waveguides.

FIG. 38 schematically illustrates a MIMO system 3800 for transmission and reception for interfacing 3D Probes/Antennas to polymer-based waveguiding structures. The system 3800 is similar to the system 3700 of FIG. 37, except that the transitions (TRANSN) using multi-pin connectors are used for interfacing the 3D probes/antennas to one or more polymer-based waveguiding structures 3706. The polymer-based waveguiding structures are connected to MIMO FEM systems using transitions with multi-pin connectors.

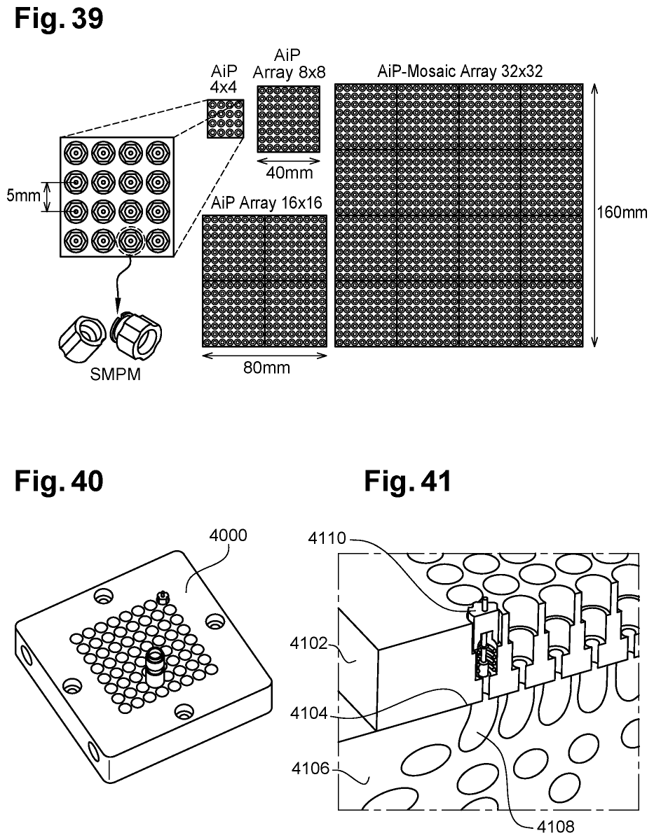

FIG. 39 illustrates mosaic-partitioning MIMO systems using multi-pin connectors for scalable large-array solutions. In particular, an example of a build-up of mosaic-partitioning MIMO systems using multi-pin connectors as described above for scalable large-array solutions is presented.

FIG. 40 is a perspective view of an RDL/RDV (Re-Distribution-Layer/Re-Distribution-Volume) device 4000, as described in more detail in the international patent application PCT/EP2021/064456 filed on 28 May 2021 (attorney reference B20083PCT). The scalability of the inter-element pitch is obtained using RDL[Re-Distribution-Layers]/RDV[re-Distribution-Volume]solutions. The RDL and RDV solutions incorporate conformal patterning for polymer-based waveguiding of RF/mmWave and optical signals.

FIG. 41 is a cross-section view of the RDL/RDV device 4000 of FIG. 40. A probe array 4102 as described herein is positioned on a surface 4104 of the main body 4106 of the RF signal distribution device 4000 in such a way that the first ends of each tunnel 4108 are aligned with the RF connectors 4110 coupled to the probes of the sensor or antenna array. In this example, the tunnels 4108 are curved to allow an RF transmission between the RF connectors 4110 and spaced with a certain pitch or surface distribution to a non-illustrated switching matrix having a different pitch or surface distribution.

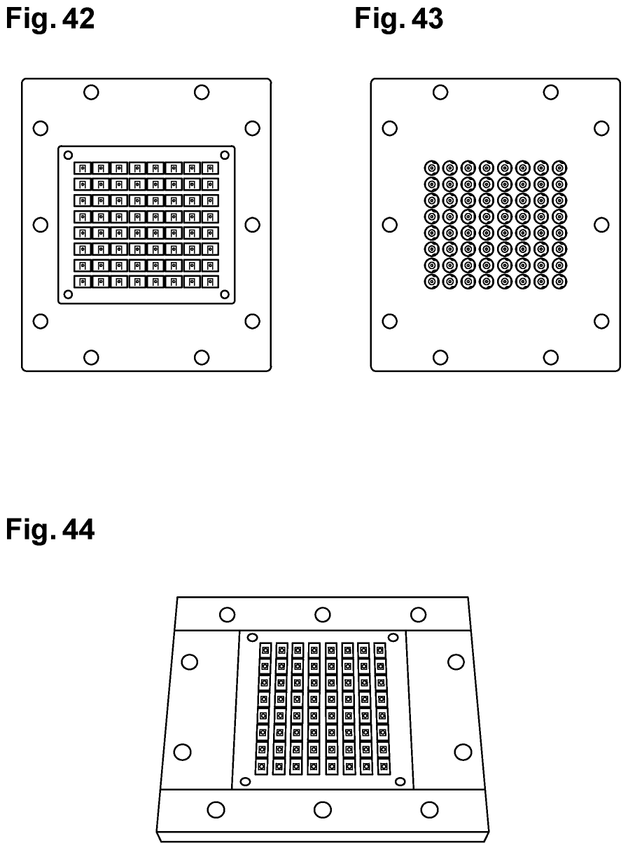

FIG. 42 to 44 are plan view of arrays of SMPM (Sub-Miniature Push-on Micro) connectors according to example embodiments of the present disclosure. In particular, FIGS. 42 to 44 illustrate a mechanism which consists of 64×SMPM connectors. The connectors have precision alignment. The SMPM standard naturally allows some misalignment in x, y and z axis. To overcome the large engage and disengage force of 64 connectors, the bracket is for example connected by torquing up 6×M3 screws and is disengaged by torquing down 6×M4 screws. The industrialized solution can be used to build massive MIMO antenna/probe array systems.

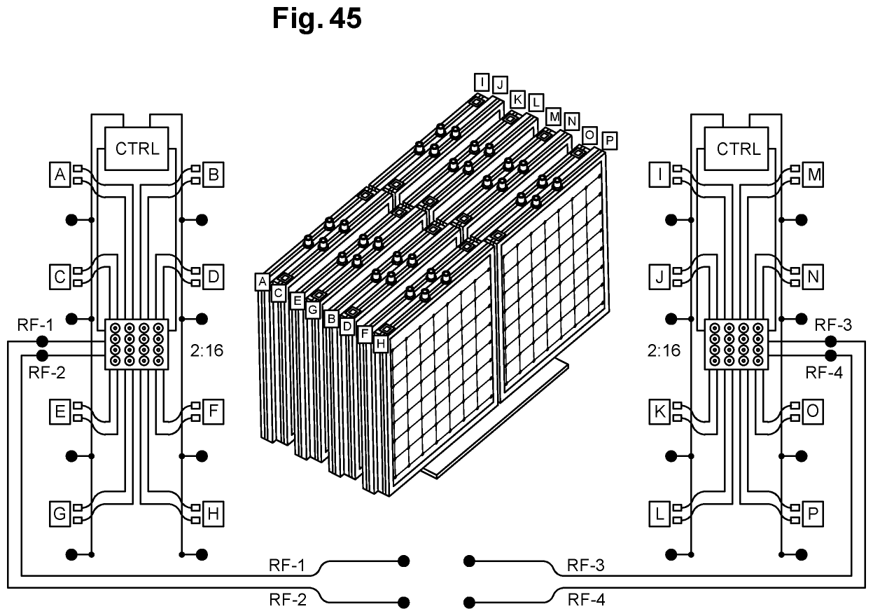

FIG. 45 schematically represents an assembly of 1024 MIMO systems built using 32×32 unitary elements composed of 4×4 Mosaic-cells with 8×8 elements each, according to an example embodiment of the present disclosure. As represented by circuit diagrams on the left and right of the figure, the solution for example permits a pair of RF signals from any of the correlators A to H to be coupled to a pair of RF outputs RF-1, RF-2, and a pair of RF signals from any of the correlators I to P to be coupled to a pair of RF outputs RF-3, RF-4. The solution is for example compliant with electric, magnetic, energy-density (combined Electric and Magnetic) probing solutions. The front-end module correlators A to P are capable of being combined with Spin-Wave and optical sensors.

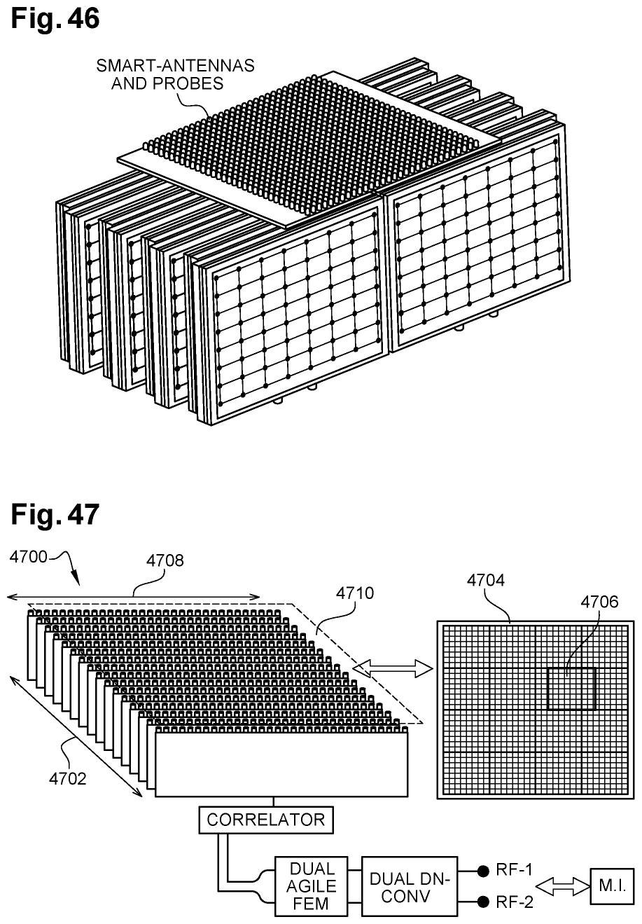

FIG. 46 is a perspective view of the assembly of FIG. 45 comprising electric, magnetic, energy-density (combined Electric and Magnetic) probing solutions according to an example embodiment of the present disclosure, with removable 3D probes/antennas (SMART-ANTENNAS AND PROBES), such as the probes/spin-wave sensors described herein.

FIG. 47 schematically illustrates a linear-array partitioning solution. In particular, while FIGS. 45 and 46 use square-based partitioning of the MIMO systems, the solution of FIG. 43 is based on linear-array partitioning. Both square and linear-array partitioning are compliant with removable 3D Probes/Antennas. An assembly 4700 is for example composed of a plurality 4702 of stacked modules, such as 32 modules, each module 4704 for example comprising a probe array, for example of size 32 by 32, although other sizes would be possible. Probe-array sub-modules 4706 are for example removable, each sub-module for example being of size 8 by 8, although other sizes would be possible. As represented by an array 4708, each module 4704 for example comprises a plurality of connectors, such as 32 connectors, which are for example smart connectors. A layer of absorbers 4710 for example covers the assembly 4700.

Various embodiments and variants have been described. Those skilled in the art will understand that certain features of these embodiments can be combined and other variants will readily occur to those skilled in the art. For example, it will be apparent to those skilled in the art that the coils as described herein could be replaced by other types of sensing elements, including mosaic sensors or the like.

Finally, the practical implementation of the embodiments and variants described herein is within the capabilities of those skilled in the art based on the functional description provided hereinabove.

1. A probe for sensing magnetic and electric fields comprising:
first and second sensing elements, the first sensing element comprising first and second terminals and the second sensing element comprising first and second terminals, the first and second sensing elements being orientated in opposite directions from each other; and
a measurement circuit configured to either:
a) measure voltage and current across the first and second terminals of the first sensing element and across the first and second terminals of the second sensing element in order to detect electric and magnetic fields; or
b) to couple the first terminal of the first sensing element and the first terminal of the second sensing element to a reference voltage and to measure a voltage present at the second terminal of the first sensing element and at the second terminal of the second sensing element in order to detect an electric field, and to couple the first terminal of the first sensing element and the first terminal of the second sensing element to an open circuit impedance and to measure a current present at the second terminal of the first sensing element and at the second terminal of the second sensing element in order to detect a magnetic field.

2. The probe of claim 1, wherein the measurement circuit is configured to perform b), the measurement circuit comprising:
at least one first switch capable of connecting the first terminal of the first sensing element:
to the open-circuit impedance such that the first sensing element forms one branch of a dipole antenna for measuring the electric field, the second terminal of the first sensing element forming a signal port; or
to the reference voltage rail via an impedance such that the first sensing element is capable of forming a magnetic field sensor, the second terminal of the first sensing element forming a signal port; and
at least one second switch configured to connect the first terminal of the second sensing element either:
to an open-circuit impedance such that the second sensing element forms the other branch of the dipole antenna for measuring the electric field, the second terminal of the second sensing element forming a signal port; or
to a reference voltage rail via an impedance such that the second sensing element is capable of forming a magnetic field sensor, the second terminal of the second sensing element forming a signal port.

3. The probe of claim 1, further comprising at least one spin-wave sensor, wherein the spin-wave sensor is for example biased by a biasing voltage, the biasing voltage for example being a DC biasing voltage.

4. The probe of claim 1, wherein the first and second sensing elements are dimensioned to receive frequencies of at least 1 GHz, and for example of at least 30 GHz.

5. The probe of claim 1, wherein the first and second sensing elements are formed in WLCSP (wafer-level-chip-scale-packaging) technology.

6. The probe of claim 1, wherein the first sensing element is implemented by a first coil and the second sensing element is implemented by a second coil.

7. A 3D energy probe comprising:
a first probe according to claim 1 having first and second sensing elements oriented to sense fields in an x direction;
a second probe according to claim 1 having first and second sensing elements oriented to sense fields in a y direction substantially perpendicular to the x direction; and
a third probe according to claim 1 having at least a first sensing element oriented to sense fields in a z direction substantially perpendicular to the x or y directions.

8. A probe array having a plurality of probing elements arranged in at least two columns and at least two rows, each probing element comprising the probe of claim 1.

9. The probe of claim 1, wherein the first and second terminals of each sensing element are coupled to the measuring circuit, or to a signal processing circuit, via a connector, the connector comprising:
a male portion comprising at least two pins, surrounded by a metallic shielding tube; and/or
a female portion comprising at least two sockets, surrounded by a metallic shielding tube.

10. The probe of claim 9, wherein each socket comprises a metal tube configured to receive, and make electrical contact with, a corresponding one of the at least two pins.

11. The probe of claim 9, wherein the metallic shielding tube is fixed to a body of the male portion of the connector, the body having, for each pin, a through-hole in which the pin is centrally positioned.

12. The probe of claim 11, wherein each pin is separated from the inside surface of its through-hole by a separation of at least 0.1 mm.

13. The probe of claim 9, wherein each pin is separated from each other pin by a spacing of at least 0.5 mm, and/or the centers of the pins are separated by a distance of at least 0.5 mm.

14. The probe of claim 9, wherein the metallic shielding tube is cylindrical, with an inner diameter 10 mm or less.

15. The probe of claim 9, wherein the at least two pins and/or the metallic shielding tube is formed of copper, aluminum, or gold.

16. The probe of claim 9, the connector comprising the male portion and the female portion, wherein, when engaged with each other, the metallic shielding tube of the male portion aligns with and electrically contacts the metallic shielding tube of the female portion.

17. A cable having at one of its extremities the male portion of the connector of the probe of claim 9, the cable comprising a first wire coupled to a first of the pins and a second wire coupled to a second of the pins, each wire being shielded by a corresponding metallic sleeve.

18. A cable having at one of its extremities the female portion of the connector of the probe of claim 9, the cable comprising a first wire coupled to a first of the sockets and a second wire coupled to a second of the sockets, each wire being shielded by a corresponding metallic sleeve.

19. The probe of claim 9, wherein the first and second terminals of each sensing element are coupled to the measuring circuit, or to a signal processing circuit, further via one or more polymer-based waveguiding structures, wherein each polymer-based waveguide structure comprises a plurality of waveguides, each waveguide being coupled to corresponding pin of the connector.

20. A modular MIMI (multiple-inputs, multiple outputs) circuit comprising a plurality of correlators configured to couple a plurality of the probes of claim 1 to a signal processor.
